(19) United States
(12) Patent Application Publication
(10) Pub. No.: US 2007/0029662 A1
(43) Pub. Date: Feb. 8, 2007

(54) Semiconductor device having termination circuit line

(76) Inventor: Jong-Joo Lee, Suwon-si (KR)

Correspondence Address: HARNESS, DICKEY & PIERCE, P.L.C., P.O. BOX 8910, RESTON, VA, 20195, US

(21) Appl. No.: 11/335,523

(22) Filed: Jan. 20, 2006

(30) Foreign Application Priority Data
Aug. 8, 2005 (KR) 2005-72386

(51) Int. Cl. H01L 23/52

(52) U.S. Cl. 257/691; 257/692; 257/693; 257/E23.153

(57) ABSTRACT

A semiconductor device may have a plurality of dielectric layers and at least one termination circuit line between the dielectric layers. The termination circuit lines may be formed over the active surface of a semiconductor substrate.

### PRIORITY STATEMENT

This U.S. non-provisional application claims priority under 35 U.S.C. § 119 from Korean Patent Application No. 2005-72386 filed Aug. 8, 2005, the contents of which are incorporated herein by reference.

### BACKGROUND

1. Field of the Invention

Example embodiment of the present invention relate generally to a semiconductor device and, more particularly, to a semiconductor device that may implement a termination circuit line.

2. Description of the Related Art

signal/data link may involve a reflection phenomenon of a signal that may result (for example) from impedance mismatching between a driver and a channel and between a channel and a receiver, which may cause a signal skew to increase a bit error rate (BER).

As shown in FIG. 1, a termination circuit 15 may be implemented in a semiconductor device 10. The termination circuit 15 may include a resistor 14 connected to an I/O terminal 13. The resistor 14 may have a resistance value matched with a characteristic impedance of a transmission line that may form a channel. The termination circuit 15 may be provided at an input/output (I/O) circuit area 12 of the semiconductor device 10.

As shown in FIG. 2, a termination circuit 25 may be implemented in a semiconductor device 20. The termination circuit 25 as an equalization circuit may use a passive equalization circuit having an I/O terminal 23 connected to a resistor 24 and a series inductor 26. The termination circuit 25 may be connected in parallel to an input capacitance 29 by a transistor (not shown) of the semiconductor device 20. The resistor 24 connected in series to the inductor 26 may provide a parallel resonance circuit having a sufficiently low Q factor. A resonance frequency may be located at a band to compensate for loss of a frequency band. The termination circuit 25 may be provided at an I/O circuit area 22 of the semiconductor device 20.

FIG. 3 shows three frequency characteristic curves 1, 310, 320. The curve 1 may be associated with a semiconductor device that may not have a termination circuit. The curves 310 and 320 may be respectively associated with semiconductor devices 10 and 20 with respective termination circuits 15 and 25. As compared to the semiconductor device that may not have a termination circuit, the semiconductor devices 10 and 20 may have better compensation effects. Further, the semiconductor device 20 having the termination circuit 25 connected to the resistor 24 and the inductor 26 (see FIG. 2) may have a better compensation effect for loss of a high frequency than the semiconductor device 10 having the termination circuit 15 connected to the resistor 14 only (see FIG. 1).

Because the termination circuits 15 and 25 may be provided at I/O circuit areas 12 and 22, respectively in the semiconductor devices 10 and 20, the conventional devices may have associated shortcomings.

For example, a resistance of the termination circuit may be fabricated from a polysilicon. The polysilicon may offer high resistance and miniaturized dimensions. However, the polysilicon may have variable resistivity depending on processes, thereby exhibiting poor signal integrity. A control switch and resistors may be connected in parallel to the termination circuit. This may lead to an additional termination circuit and a complicated termination circuitry, thereby resulting in increases of electric power consumption and/or power supply noise, for example.

Further, an inductor in a semiconductor device may be several mm thick, which may increase the size of a semiconductor device. Dielectric layers in the semiconductor device may increase an inherent parasitic capacitance of an inductor.

### SUMMARY

According to an example, non-limiting embodiment, a semiconductor device may include a semiconductor substrate having an active surface with a circuit wiring layer. The circuit wiring layer may include signal patterns and a power pattern or a ground pattern. A passivation layer may be provided on the active surface of the semiconductor substrate. A first dielectric layer may be provided on the passivation layer. A plurality of termination circuit lines may be provided on the first dielectric layer. The termination circuit lines may be connected to the signal patterns and the power pattern and/or the ground pattern. The termination circuit lines may be metal lines. A second dielectric layer may be provided on the termination circuit lines.

According to another example, non-limiting embodiment, a semiconductor device may include a semiconductor substrate having an active surface with a circuit wiring layer. The circuit wiring layer may include power patterns connected to power pads, ground patterns connected to ground pads and signal patterns connected to signal pads. A passivation layer may be provided on the active surface of the semiconductor substrate exposing the power pads, the ground pads and the signal pads. A plurality of dielectric layers may be provided on the passivation layer exposing the power pads, the ground pads and the signal pads. A plurality of termination circuit lines may be provided between the dielectric layers and connected to the signal pads and the power patterns and/or the ground patterns. The termination circuit lines may be metal lines.

According to another example, non-limiting embodiment, a semiconductor device may include a semiconductor substrate having an active surface with a circuit wiring layer including a signal pattern. A termination circuit line may be provided on the substrate and connected to the signal pattern. The termination circuit line may be superposed above the circuit wiring layer.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a circuit diagram of an example of a conventional termination circuit line.

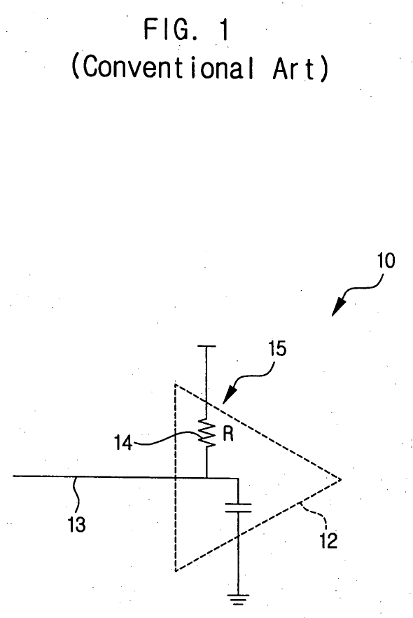

FIG. 2 is a circuit diagram of another example of a conventional termination circuit line.

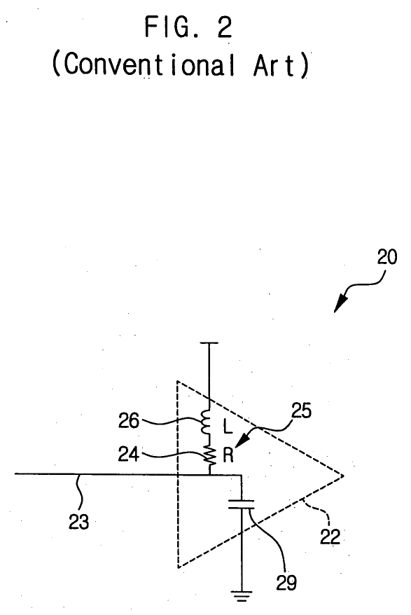

FIG. 3 is a graph illustrating a frequency characteristic of an input impedance of the termination circuit lines of FIGS. 1 and 2.

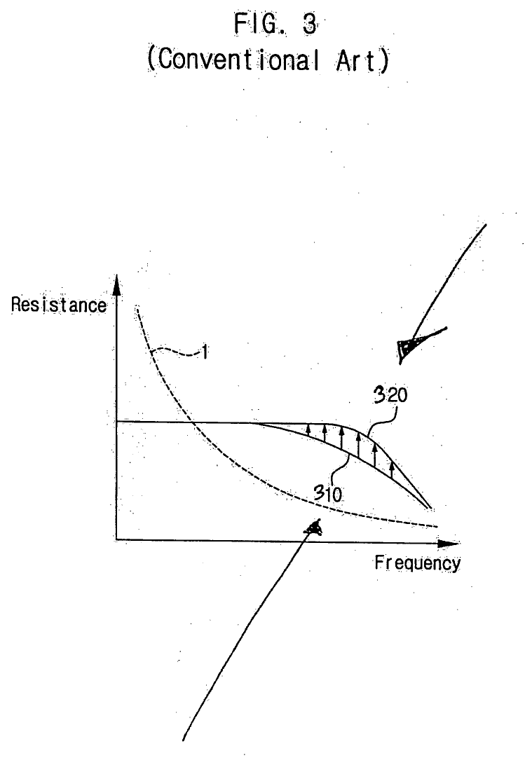

FIG. 4 is a plan view of a semiconductor device having a termination circuit line in accordance with an example embodiment of the present invention.

FIG. 5 is a cross-sectional view of a semiconductor device having a termination circuit line in accordance with an example embodiment of the present invention.

FIG. 6 is an equivalent circuit diagram of the termination circuit line of FIG. 5.

FIG. 7 is an equivalent circuit diagram of a termination control switch and the termination circuit line of FIG. 5.

FIG. 8 is a cross-sectional view of a semiconductor device having a termination circuit line in accordance with another example embodiment of the present invention.

The drawings are provided for illustrative purposes only and are not drawn to scale. The spatial relationships and relative sizing of the elements illustrated in the various embodiments may be reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to example embodiments of the invention.

### DETAILED DESCRIPTION OF EXAMPLE, NON-LIMITING EMBODIMENTS

Example, non-limiting embodiments of the present invention will be described with reference to the accompanying drawings. This invention may, however, be embodied in many different forms and should not be construed as limited to example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Well-known structures and processes are not described or illustrated in detail to avoid obscuring the present invention. Like reference numerals are used for like and corresponding parts of the various drawings.

Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

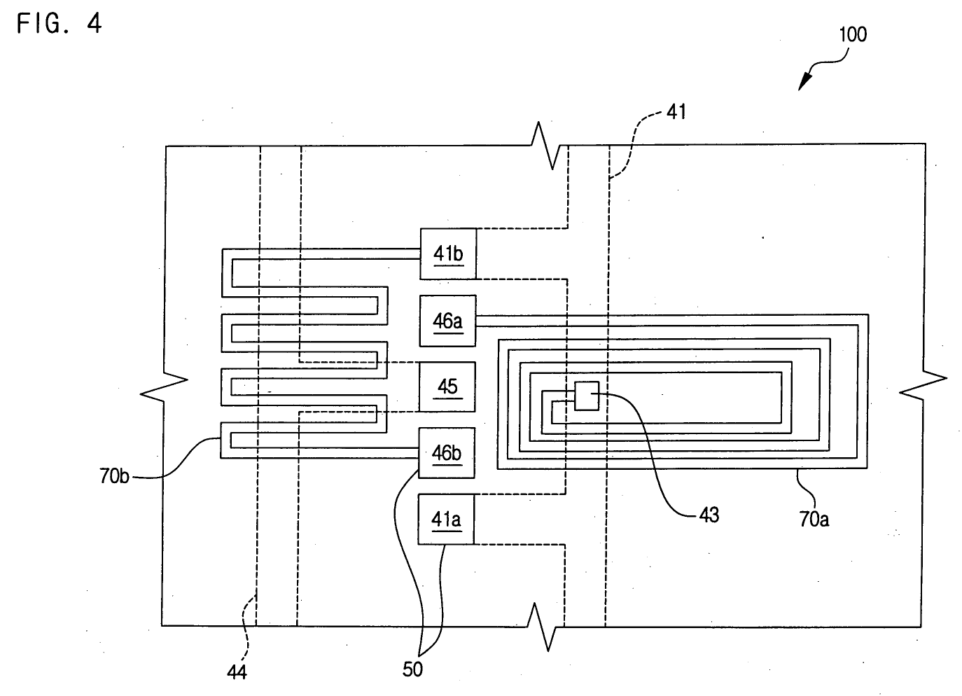

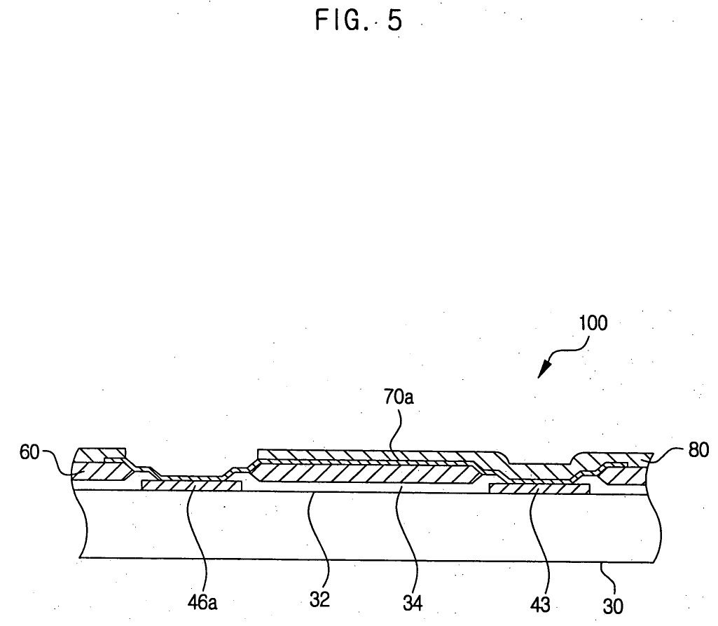

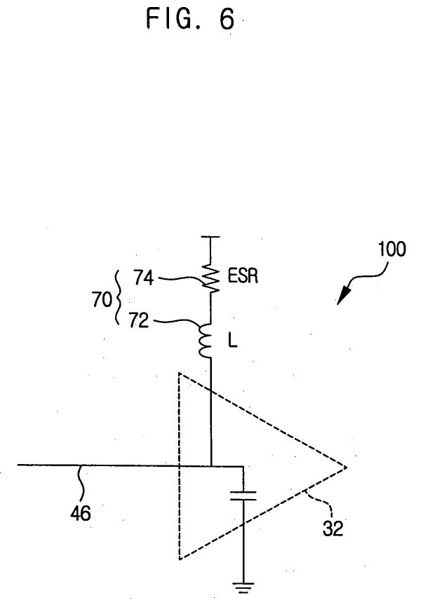

FIG. 4 is a plan view of a semiconductor device 100 having a termination circuit line in accordance with an example embodiment of the present invention. FIG. 5 is a cross-sectional view of a semiconductor device 100 having a termination circuit line in accordance with an example embodiment of the present invention. FIG. 6 is an equivalent circuit diagram of the termination circuit line of FIG. 5.

Referring to FIGS. 4 through 6, the semiconductor device 100 may include a semiconductor substrate 30. The semiconductor substrate 30 may have an active surface 32 that may support a circuit wiring layer. The circuit wiring layer may include (for example) power patterns and/or ground patterns. In an example embodiment, the circuit wiring layer may include a power pattern 41 and a ground pattern 44. The semiconductor substrate 30 may also include a signal pattern (not shown). A passivation layer 34 may be provided on the active surface 32 of the semiconductor substrate 30. A first dielectric layer 60 may be provided on the passivation layer 34.

Termination circuit lines 70a and 70b may be provided on the first dielectric layer 60. By way of example only, the termination circuit lines 70a and 70b may be fabricated via a wafer level redistribution process. The termination circuit lines 70a and 70b may be connected to the signal pattern and at least one of the power pattern 41 and the ground pattern 44. A second dielectric layer 80 may be provided on the termination circuit lines 70a and 70b.

The termination circuit lines 70a and 70b may provide the functionality of a resistor and an inductor. With reference to FIG. 6, for example, the termination circuit 70 may serve as an inductor 72 connected in series to a resistor 74, which may eliminate the need for a separate resistor and/or inductor. Since the termination circuit lines 70a and 70b may be fabricated via a wafer level redistribution process, a resistance value and an inductance value of the termination circuit lines 70a and 70b may remain stable to provide improved signal integrity.

In an example embodiment, the semiconductor substrate 30 may have a plurality of chip pads 50. The chip pads 50 may be provided on the active surface 32 and be electrically connected to the circuit wiring layer. By way of example only, the chip pads 50 may be fabricated from Al, and the passivation layer 34 may be fabricated from oxide, nitride, and/or an alloy thereof.

The chip pads 50 may include (for example) power pads 41a and 41b that may be connected to the power pattern 41, ground pads 45 that may be connected to the ground pattern 44, and signal pads 46a and 46b that may be connected to the signal patterns (not shown). By way of example only, the chip pads 50 may be arranged in a line on the active surface 32.

The first dielectric layer 60 may cover the passivation layer 34 and may expose the chip pads 50.. The first dielectric layer 60 may have a low dielectric constant to reduce a parasitic capacitance of the termination circuit lines 70a and 70b. The first dielectric layer 60 may be fabricated from polymer, for example polyimide, benzocyclobutene, polybenzoxazole, and/or epoxy. By way of example only, the thickness of the first dielectric layer 60 may be several μm or more.

The first dielectric layer 60 may be fabricated via a conventional spin coating method. The first dielectric layer 60 may be patterned via a typical photolithographic process to expose the chip pads 50.

The termination circuit lines 70a and 70b may be elongated metal lines on the first dielectric layer 60. From a functional standpoint, the elongated metal line may serve as the resistor 74 connected to the inductor 72 to form the termination circuit 70 of an input/output circuit. By way of example only, a resistance value may be determined according to type and/or dimension of the metal used, and an inductance value may be determined according to the dimension, length and/or shape of the metal line. Therefore, a resistance value of the termination circuit lines 70a and 70b may be an equivalent series resistance value (ESR).

The termination circuit lines 70a and 70b may be arranged over (and spaced apart from) the active surface 32 and the circuit wiring layer (inclusive of the power patterns, the ground patterns and/or the signal patters). In this way, the available area for forming the termination circuit line may be increased. For example, because the termination circuit lines 70a and 70b may be superposed above the active surface 32, they may be designed as desired, without having to fit the termination circuit lines between the areas of the active surface 32 occupied by the circuit wiring layer.

In an example embodiment, the termination circuit lines 70a and 70b may connect the signal pads 46a and 46b (which may be connected to an I/O circuit 46 (e.g., the signal pattern) to be terminated) to the power pattern 41. The termination circuit lines 70a and 70b may be fabricated using conventional thin-film deposition methods, for example electroplating, sputtering, and/or evaporation, and also a photolithographic process. The termination circuit lines 70a and 70b may have numerous and alternative geometric shapes. For example, the termination circuit lines may have a meandering shape, a spiral shape and/or a solenoidal shape. It will be appreciated that the termination circuit lines 70 and 70b may not be limited to any particular shape. In an example embodiment, each termination circuit line may have cross sectional shapes that may be uniform along the length of the termination circuit line. In alternative embodiments, each termination circuit line may have cross sectional shapes that may vary along the length of the termination circuit line.

In an example embodiment, the termination circuit line 70b may connect the signal pad 46b to the power pad 41 b. Also, the termination circuit line 70a may connect to a portion of the power pattern 41 spaced apart from the signal pad 46a and the power pad 41b.

For example, a connection pad 43 and/or a via may be implemented to connect the termination circuit line 70a to the spaced apart portion of the power pattern 41. The connection pad 43 may be provided on the active surface 32 corresponding to the power pattern 41 and be connected to the power pattern 41. The via may be formed to penetrate the passivation layer 34 and the first dielectric layer 60. An example embodiment may implement the connection pad 43.

The signal pads 46a and 46b may be provided between the power pads 70a and 70b. The ground pad 45 may be provided between the signal pads 46a and 46b. The power pattern 41 may be provided on one side of the chip pads 50, and the ground pattern 44 may be provided at the other side of the chip pads 50. The signal pad 46a may be connected to the connection pad 43 through the termination circuit line 70a. The signal pad 46b may be connected to the power pad 70b through the termination circuit line 70b. The termination circuit line 70a may have a spiral shape and be superposed above the power pattern 41. The termination circuit line 70b may have a meandering shape and be superposed above the ground pattern 44.

In an example embodiment, the termination circuit lines 70a and 70b may be connected to the power pattern 41. In alternative embodiments, the termination circuit lines 70a and 70b may be connected to the ground pattern 44 or to both the power pattern 41 and the ground pattern 44.

The second dielectric layer 80 may cover the first dielectric layer 60 and the termination circuit lines 70a and 70b, and may leave the chip pads 50 exposed. The second dielectric layer 80 may be fabricated in the same manner as the first dielectric layer 60.

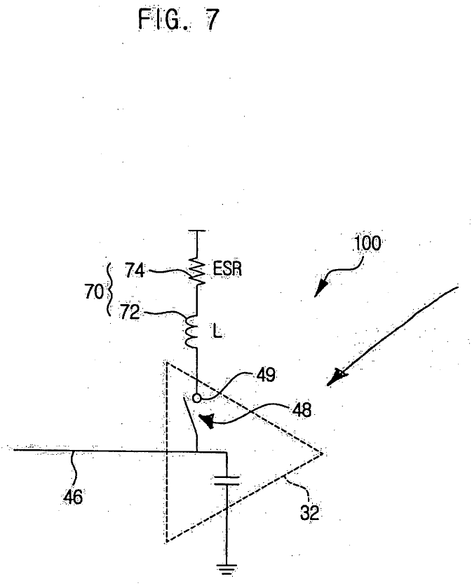

FIG. 7 is an equivalent circuit diagram of a termination control switch connected to the termination circuit line of FIG. 5.

Referring to FIG. 7, a termination control switch 48 may be provided on the active surface 32. The termination control switch 48 may be configured to turn on and off the termination circuit 70. The termination control switch 48 may have a control switch terminal 49 connected to the termination circuit 70. The termination control switch 48 may be a switch pad, connectable to the termination circuit 70. Alternatively, the termination control switch 48 may be configured so that the control switch terminal 49 may be connected to the termination circuit 70 using a via.

In an example embodiment, the termination circuit line may have a single layered structure. In alternative embodiments, a multilayered termination circuit line (which may include a ground layer and/or a power layer) may be suitably implemented.

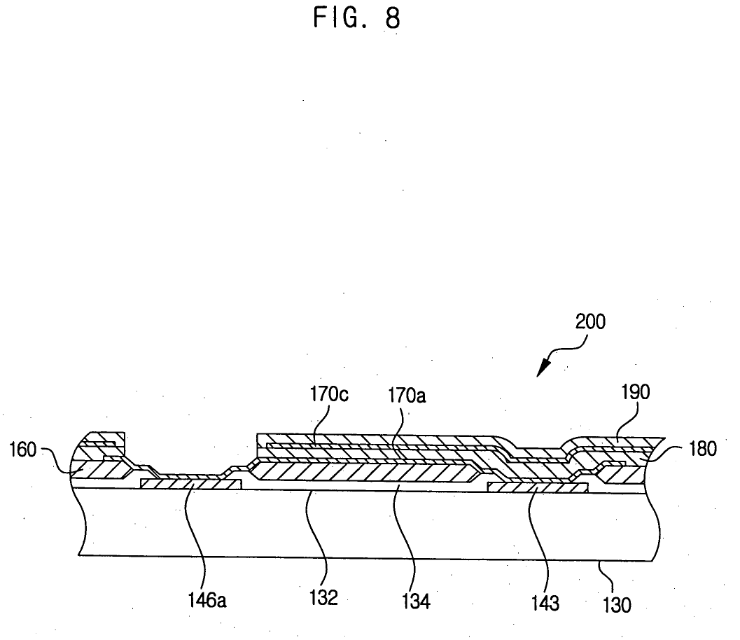

FIG. 8 is a cross-sectional view of a semiconductor device 200 having a termination circuit line in accordance with another example embodiment of the present invention.

Referring to FIG. 8, a multilayered termination circuit line 170a may include at least one power layer and/or a ground layer. The multilayered termination circuit line 170a may provide stable power supply and noise shield effects. In an example embodiment, a ground layer 170c may be provided on a second dielectric layer 180. A third dielectric layer 190 may be provided on the ground layer 170c. The termination circuit line 170a may be interposed between a first dielectric layer 160 and the second dielectric layer 180.

In addition (or as an alternative), a power layer (not shown) may be provided between the second dielectric layer 180 and the third dielectric layer 190.

For example, the power layer may be spaced apart from the ground layer.

While example, non-limiting embodiments have been shown and described, it will be understood by those skilled in the art that various changes in form and details may be made therein without departing from the spirit and scope of the invention as defined by the appended claims.

What is claimed is:

1. A semiconductor device comprising:
a semiconductor substrate having an active surface with a circuit wiring layer including signal patterns and at least one of a power pattern and a ground pattern;
a passivation layer provided on the active surface of the semiconductor substrate;
a first dielectric layer provided on the passivation layer;
a plurality of termination circuit lines provided on the first dielectric layer and connected to the signal patterns and at least one of the power pattern and the ground pattern, the termination circuit lines being metal lines; and
a second dielectric layer provided on the termination circuit lines.

2. The device of claim 1, wherein the termination circuit line has one of a meandering shape, a spiral shape and a solenoidal shape.

3. The device of claim 2, wherein the power pattern has power pads, the ground pattern has ground pads and the signal pattern has signal pads, and the power pads, the ground pads and the signal pads are exposed through the second dielectric layer.

4. The device of claim 3, wherein the termination circuit lines include at least one termination circuit line connected to the signal pad and one of the power pad and the ground pad.

5. The device of claim 3, wherein the termination circuit lines include at least one termination circuit line connected to the signal pad and one of the power pattern and the ground pattern.

6. The device of claim 5, wherein one of the power pattern and the ground pattern includes a connection pad connected to the at least one termination circuit line.

7. The device of claim 1, wherein the signal pattern includes a termination control switch having a terminal, and the termination circuit lines include at least one termination circuit line connected to the terminal of the termination control switch.

8. The device of claim 7, wherein the terminal of the termination control switch is a pad on the active surface.

9. The device of claim 8, wherein the terminal of the termination control switch is connected to the termination circuit line using a via.

10. The device of claim 1, wherein the thickness of the first dielectric layer is at least several am.

11. A semiconductor device comprising:
a semiconductor substrate having an active surface with a circuit wiring layer including power patterns connected to power pads, ground patterns connected to ground pads and signal patterns connected to signal pads;
a passivation layer provided on the active surface of the semiconductor substrate exposing the power pads, the ground pads and the signal pads;
a plurality of dielectric layers provided on the passivation layer exposing the power pads, the ground pads and the signal pads; and
a plurality of termination circuit lines provided between the dielectric layers and connected to the signal pads and one of the power patterns and the ground patterns, the termination circuit lines being metal lines.

12. The device of claim 11, wherein the plurality of dielectric layers comprises at least three layers, and the termination circuit lines are a multilayered structure interposed between the dielectric layers.

13. The device of claim 12, wherein at least one termination circuit line serves as one of the ground layer and the power layer.

14. A semiconductor device comprising:
a semiconductor substrate having an active surface with a circuit wiring layer including a signal pattern;
a termination circuit line provided on the substrate and connected to the signal pattern, the termination circuit line superposed above the circuit wiring layer.

15. The device of claim 14, wherein the termination circuit line is fabricated from a metal.

16. The device of claim 14, wherein the termination circuit line is superposed above a power pattern of the circuit wiring layer.

17. The device of claim 14, wherein the termination circuit line is superposed above a ground pattern of the circuit wiring layer.

18. The device of claim 14 comprising a plurality of the termination circuit lines.

19. The device of claim 14, wherein the termination circuit line has a single layer structure.

20. The device of claim 14, wherein the termination circuit line has a multilayered structure.
